(19) United States
(12) Patent Application Publication
(10) Pub. No.: US 2023/0266064 A1
(43) Pub. Date: Aug. 24, 2023

(54) HEAT EXCHANGE DEVICE USING SEAWATER

(71) Applicant: Seung Jae OH, Jeollanam-do (KR)

(72) Inventors: Seung Jae OH, Jeollanam-do (KR); Jeong Seok HA, Gwangju (KR)

(73) Assignee: Seung Jae OH, Jeollanam-do (KR)

(21) Appl. No.: 18/012,947

(22) PCT Filed: Nov. 27, 2020
(86) PCT No.: PCT/KR2020/017189

§ 371 Date: Dec. 26, 2022

(30) Foreign Application Priority Data
Jun. 26, 2020 (KR) 10-2020-0078193

(51) Int. Cl. F28D 1/02

(52) U.S. Cl. CPC F28D 1/022

(57) ABSTRACT

The present disclosure provides a heat exchange device using seawater including: a heat exchanger through which liquefied natural gas is passed and vaporized; a first supply line connected to the heat exchanger and supplying seawater to the heat exchanger; a first discharge line through which the seawater discharged from the heat exchanger flows in; a reservoir to which the seawater flows in and out; a heat source installed in the reservoir and heating the seawater flowed in the reservoir; a discharge connection line connecting the first discharge line and the reservoir, and selectively supplying the seawater flowing through the first discharge line to the reservoir; and a second discharge line for discharging the seawater from the reservoir to the sea.

### TECHNICAL FIELD

The present disclosure relates to a heat exchange device using seawater, and more particularly, to a heat exchange device which vaporizes liquefied natural gas using seawater and discharges seawater heat-exchanged with a data center to the sea.

### BACKGROUND

In general, natural gas (NG) is transported to a remote location by a liquefied natural gas carrier in a state of being liquefied as liquefied natural gas (LNG) in a cryogenic state at a production site for the convenience of transport. The liquefied natural gas is obtained by cooling the natural gas to a cryogenic temperature of about -163° C. at the atmospheric pressure and the volume thereof is reduced to about 1/600 compared to that of the natural gas in a gaseous state. Therefore, the liquefied natural gas is very suitable for long-distance transport through sea.

After reaching the destination, the liquefied natural gas should be vaporized again as the natural gas and supplied to each supplier. At this time, in order to vaporize the liquefied natural gas into the natural gas, the liquefied natural gas may be heat-exchanged with seawater. In this case, the liquefied natural gas at -163° C. is vaporized into the natural gas at 0° C. and the seawater is cooled from about 15° C. to 12° C.

Here, in a case where the seawater cooled by the liquefied natural gas is discharged to the sea as it is, it may cause a serious problem to the marine ecosystem, so it is necessary to heat the cooled seawater again and then discharge the seawater to the sea.

### SUMMARY OF INVENTION

### Technical Problem

The present disclosure is developed for the above-mentioned necessity, and an object of the present disclosure is to provide a heat exchange device using seawater which discharges seawater heat-exchanged with liquefied natural gas to the sea after heat-exchanged with a data center to minimize damage to the marine ecosystem caused by the seawater discharged to the sea and enable cooling of the data center.

### Solution to Problem

According to an embodiment of the present disclosure, there is provided a heat exchange device using seawater including: a heat exchanger through which liquefied natural gas is passed and vaporized; a first supply line connected to the heat exchanger and supplying seawater to the heat exchanger; a first discharge line through which the seawater discharged from the heat exchanger flows in; a reservoir to which the seawater flows in and out; a heat source installed in the reservoir and heating the seawater flowed in the reservoir; a discharge connection line connecting the first discharge line and the reservoir, and selectively supplying the seawater flowing through the first discharge line to the reservoir; and a second discharge line for discharging the seawater from the reservoir to the sea.

The heat exchange device according to the present disclosure may further include a case surrounding the heat source.

A lower portion of the heat source may be immersed in the reservoir, and the case may include a bottom case surrounding the lower portion of the heat source.

The heat source may be accommodated inside the reservoir, and the case may further include an upper cover that is disposed on an upper side of the bottom case and surrounds an upper portion of the heat source.

The heat exchanger may include a heat exchange cylinder having a hollow cylindrical shape; and a gas flow line which penetrates the inside of the heat exchange cylinder and through which liquefied natural gas passes.

The heat source may be a data center.

The heat exchange device according to the present disclosure may further include a supply connection line connecting the first supply line and the reservoir, and selectively supplying the seawater flowed in the reservoir to the first supply line; and a second supply line through which the seawater is flowed in the reservoir from the sea.

In a first mode of the present disclosure, the seawater supplied to the heat exchanger from the sea through the first supply line may be discharged to the sea through the first discharge line.

In a second mode of the present disclosure, the seawater supplied to the heat exchanger from the sea through the first supply line may be supplied to the reservoir through the first discharge line and the discharge connection line, and then is discharged to the sea through the second discharge line.

In a third mode of the present disclosure, the seawater may circulate through a closed loop that sequentially connects the reservoir, the supply connection line, the first supply line, the heat exchanger, the first discharge line, the discharge connection line, and the reservoir.

In a fourth mode of the present disclosure, the seawater supplied to the reservoir through the second supply line may flow along the supply connection line, the first supply line, the heat exchanger, the first discharge line, the discharge connection line, the reservoir, and the second discharge line.

In a fifth mode of the present disclosure, the seawater supplied to the heat exchanger through the first supply line may be supplied to the reservoir through the first discharge line and the discharge connection line, some of the seawater supplied to the reservoir may be supplied to the first supply line through the supply connection line, and the other thereof may be discharged to the sea through the second discharge line.

In a sixth mode of the present disclosure, the seawater supplied to the heat exchanger through the first supply line may circulate through the first discharge line, the discharge connection line, the reservoir, the supply connection line, and the first supply line.

In a seventh mode of the present disclosure, the seawater may be supplied to the heat exchanger through the first supply line, and the seawater supplied to the reservoir through the second supply line may be supplied to the heat exchanger through the supply connection line and the first supply line, and the seawater passing through the heat exchanger may be discharged to the sea through the first discharge line, the discharge connection line, the reservoir, and the second discharge line.

### Advantageous Effects of Invention

According to the heat exchange device using seawater according to the present disclosure, it is possible to vaporize the liquefied natural gas into the natural gas using the seawater, and cool the data center using the seawater in a cooled state by heat-exchanging process with the liquefied natural gas, and prevent damage to the marine ecosystem by discharging the seawater reheated by the data center to the sea.

### BRIEF DESCRIPTION OF DRAWINGS

FIG. 1 is a perspective view of a heat exchange device using seawater according to an embodiment of the present disclosure.

FIG. 2 is a perspective view of a heat source and a case shown in FIG. 1.

FIGS. 3 to 9 are views showing operations in the first to seventh modes of the present disclosure.

### BEST MODE FOR INVENTION

Although the present disclosure is described with reference to the embodiments shown in the drawings which are merely exemplary, it will be understood by those skilled in the art that various modifications and equivalent other embodiments are possible therefrom. Therefore, the true technical protection scope of the present disclosure should be determined by the technical spirit of the appended claims.

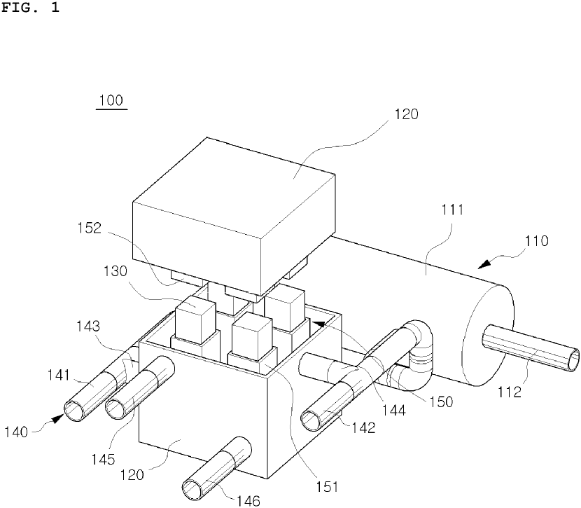

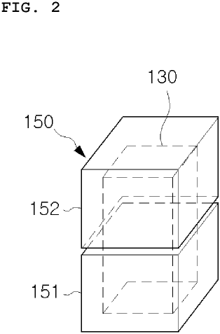

Referring to FIGS. 1 and 2, a heat exchange device 100 using seawater according to an embodiment of the present disclosure includes a heat exchanger 110, a reservoir 120, a heat source 130, a seawater flow line 140, and a case 150.

Liquefied natural gas passes through the inside of the heat exchanger 110, and the heat exchanger 110 vaporizes the liquefied natural gas to the natural gas. To this end, the heat exchanger 110 includes a heat exchange cylinder 111 and a gas flow line 112. The heat exchange cylinder 111 is formed in a hollow cylindrical shape and the seawater is supplied to the inside thereof through the seawater flow line 140. The gas flow line 112 penetrates the heat exchange cylinder 111 and the liquefied natural gas passes therethrough. As the seawater on the inside of the heat exchange cylinder 111 heats the gas flow line 112, the liquefied natural gas passing through the gas flow line 112 is vaporized into natural gas.

In general, the liquefied natural gas supplied to the gas flow line 112 is -163° C. and the seawater flowed into the heat exchange cylinder 111 through the seawater flow line 140 is about 15° C. After the liquefied natural gas is vaporized into natural gas at 0° C. by the seawater, the liquefied natural gas is discharged from the gas flow line 112, and the seawater, which exchanges heat with the liquefied natural gas to vaporize the liquefied natural gas, is cooled to 12° C. approximately and is discharged from the heat exchange cylinder 111.

The seawater flows into and out of the reservoir 120. The heat source 130 is accommodated inside the reservoir 120 and heats the seawater flowed into the reservoir 120. The case 150 surrounds the heat source 130 and prevents the heat source 130 from coming into direct contact with the seawater present inside the reservoir 120.

Only a lower portion of the heat source 130 may be immersed in the reservoir 120, or the entire heat source 130 may be immersed in the reservoir 120. The case 150 may include a bottom case 151 and an upper cover 152. The bottom case 151 surrounds the lower portion of the heat source 130. The upper cover 152 is installed in the heat source 130 in a case where the entire heat source 130 is immersed in the reservoir 120, is disposed on the upper side of the bottom case 151, and surrounds an upper portion of the heat source 130. Of course, as shown in FIG. 1, the reservoir 120 may be designed to vertically surround both the heat source 130 and the case 150.

The heat source 130 may be a data center. The data center is a facility that collects equipment that needs to provide IT services, such as a server, a storage, and a network device, in one place, operates 24 hours a day, 365 days a year, and integrally manages the equipment. The data center receives power and operates in real-time, thereby steadily generating heat. Therefore, the data center needs to be continuously cooled.

As described above, in a case where the heat source 130 is the data center, the data center can be cooled using the seawater cooled by vaporizing the liquefied natural gas, and the seawater is heated by heat-exchanging process with the data center, so that the temperature thereof rises. Therefore, by discharging the seawater in a warm state to the sea, it is possible to prevent damage to the marine ecosystem by cold drainage. On the other hand, since the heat source 130 is surrounded by the case 150, in a case where the heat source 130 is the data center, cooling of the data center by the seawater is indirectly cooled.

The seawater flow line 140 connects the heat exchanger 110 and the reservoir 120, and includes a first supply line 141, a first discharge line 142, a discharge connection line 144, a second discharge line 146, a supply connection line 143, and a second supply line 145.

The first supply line 141 is connected to the heat exchange cylinder 111 of the heat exchanger 110 and supplies the seawater flowed in from the sea or the reservoir 120 to the heat exchange cylinder 111. The first discharge line 142 is connected to the heat exchange cylinder 111, the seawater discharged from the heat exchange cylinder 111 flows therein, and the first discharge line 142 supplies the flowed-in seawater to the reservoir 120 through the discharge connection line 144, or discharges the seawater to the sea.

The discharge connection line 144 connects the first discharge line 142 and the reservoir 120, and selectively supplies the seawater, which flows through the first discharge line 142, to the reservoir 120. The second discharge line 146 selectively discharges the seawater from the reservoir 120 to the sea. Although not shown in the drawings, a three-way valve may be installed at a connection portion between the discharge connection line 144 and the first discharge line 142. The three-way valve changes the direction of the flowing seawater so that the seawater flowing into the first discharge line 142 is supplied to the reservoir 120 or discharged to the sea.

The supply connection line 143 connects the first supply line 141 and the reservoir 120, and selectively supplies the seawater present in the reservoir 120 to the first supply line 141. The second supply line 145 selectively introduces the seawater from the sea to the reservoir 120.

As shown in FIG. 1, the first supply line 141 and the first discharge line 142 may be disposed to be spaced apart from each other with the reservoir 120 interposed therebetween. In addition, the second supply line 145 and the second discharge line 146 may be disposed on the opposite side of the heat exchanger 110 with respect to the reservoir 120. In addition, the second supply line 145 and the second discharge line 146 may be disposed to be biased toward the first supply line 141 and the first discharge line 142, respectively. However, this is only an example, and a disposition relationship of the seawater flow line 140 may be modified according to a purpose of an operator.

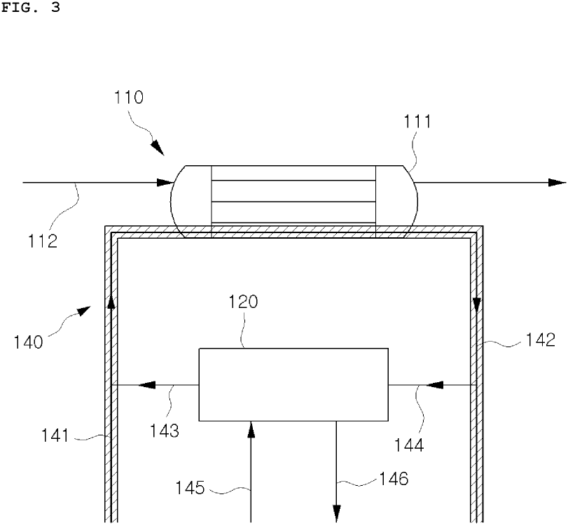

Hereinafter, a detailed operation of the heat exchange device 100 using the seawater according to an embodiment of the present disclosure will be described with reference to FIGS. 3 to 9.

Referring to FIG. 3, in a first mode of the present disclosure, the seawater supplied from the sea to the heat exchanger 110 through the first supply line 141 is discharged to the sea through the first discharge line 142. The first mode is operated in a case where cooling of the data center is unnecessary or in a case where the temperature of the seawater discharged from the heat exchanger 110 is relatively high.

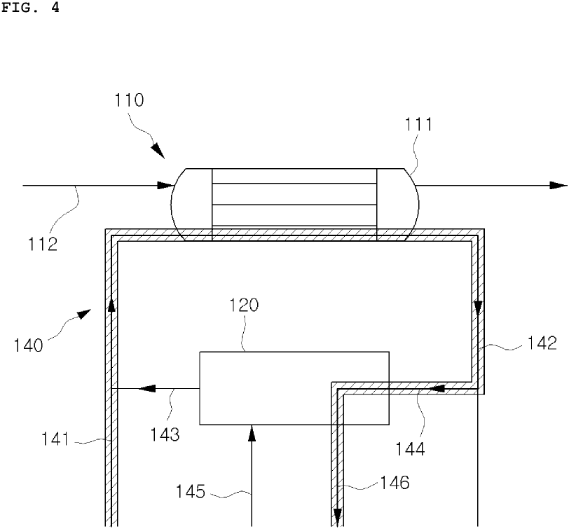

Referring to FIG. 4, in a second mode of the present disclosure, the seawater supplied from the sea to the heat exchanger 110 through the first supply line 141 is supplied to the reservoir 120 through the first discharge line 142 and the discharge connection line 144, and then is discharged to the sea through the second discharge line 146. The second mode is operated in a case where cooling of the data center is required or the temperature of the seawater discharged from the heat exchanger 110 is relatively low. In the second mode, the seawater, which is discharged from the heat exchanger 110, is in the process of heat-exchange with the data center and then is discharged to the sea.

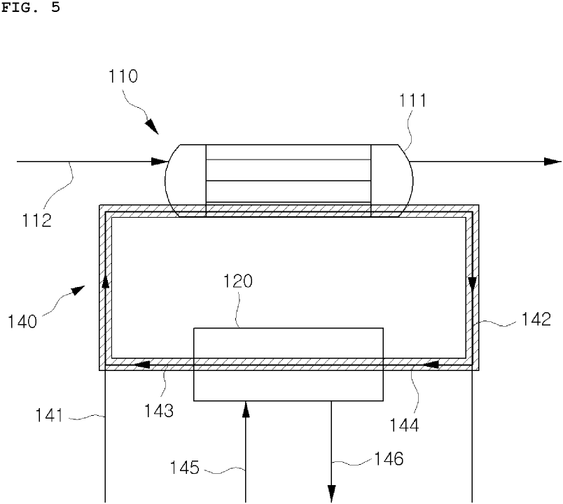

Referring to FIG. 5, in a third mode of the present disclosure, the seawater circulates through a closed loop sequentially connecting the reservoir 120, the supply connection line 143, the first supply line 141, the heat exchanger 110, the first discharge line 142, the discharge connection line 144, and the reservoir 120. The third mode is operated in a case where an amount of heat supplied from the seawater to the liquefied natural gas in the heat exchanger 110 is equal to an amount of heat supplied from the data center to the seawater in the reservoir 120. Accordingly, in the third mode, the heat exchange is performed in the heat exchanger 110 without an additional inflow of seawater from the sea to the heat exchanger 110.

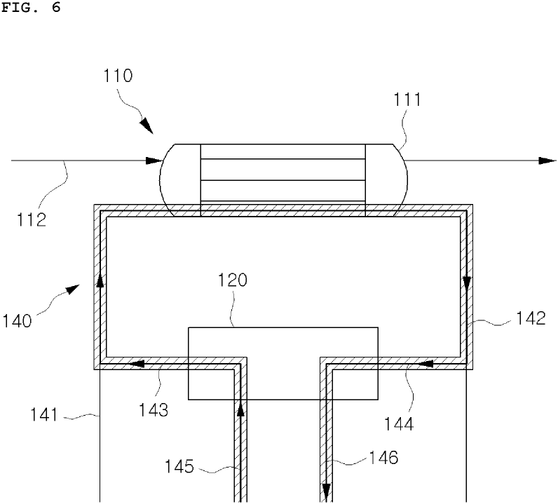

Referring to FIG. 6, in a fourth mode of the present disclosure, the seawater, which is supplied to the reservoir 120 through the second supply line 145, flows along the supply connection line 143, the first supply line 141, the heat exchanger 110, the first discharge line 142, the discharge connection line 144, the reservoir 120, and the second discharge line 146. The fourth mode is operated when the seawater temperature is low, such as in winter, and the amount of heat required when the liquefied natural gas is vaporized cannot be sufficiently supplied from the seawater, and the seawater of the sea is preheated in the reservoir 120 and then is sent to the heat exchanger 110.

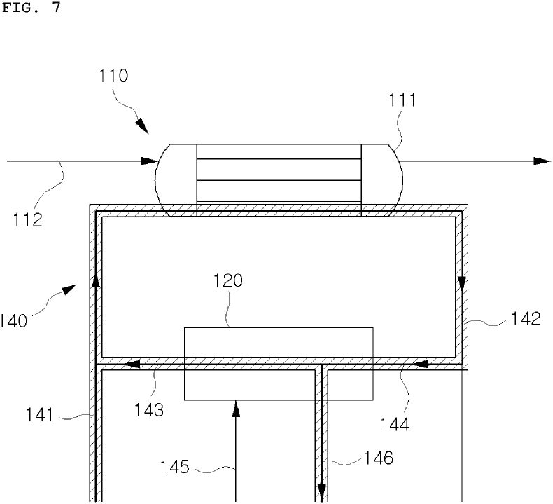

Referring to FIG. 7, in a fifth mode of the present disclosure, the seawater, which is supplied to the heat exchanger 110 through the first supply line 141, is supplied to the reservoir 120 through the first discharge line 142 and the discharge connection line 144. Some of the seawater supplied to the reservoir 120 is supplied to the first supply line 141 through the supply connection line 143, and the other portion thereof is discharged to the sea through the second discharge line 146. The fifth mode is operated when it is desired to optimally supply the heat of vaporization required for the liquefied natural gas, and in a case where the required heat of vaporization of the liquefied natural gas increases, and in a case where the supply of the seawater from the sea to the device is increased and the required heat of vaporization of the liquefied natural gas decreases, discharge of the seawater from the device to the sea is increased.

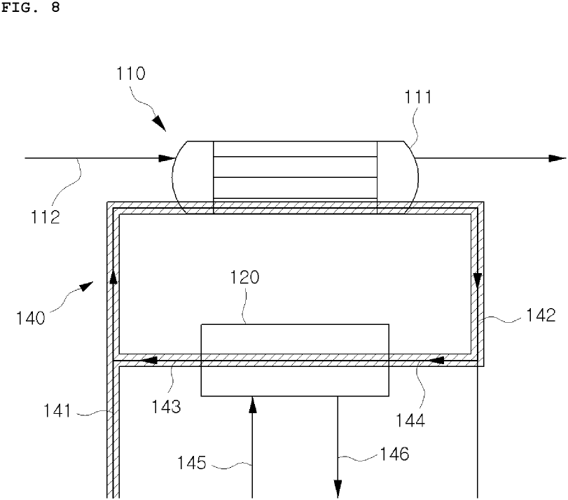

Referring to FIG. 8, in a sixth mode of the present disclosure, the seawater, which is supplied to the heat exchanger 110 through the first supply line 141, circulates along the first discharge line 142, the discharge connection line 144, the reservoir 120, the supply connection line 143, and the first supply line 141. In the sixth mode, in a case where the amount of the seawater flowing to the heat exchanger 110 and the reservoir 120 is insufficient, the amount of the seawater flowing to the device is supplemented through an additional inflow of the seawater from the sea.

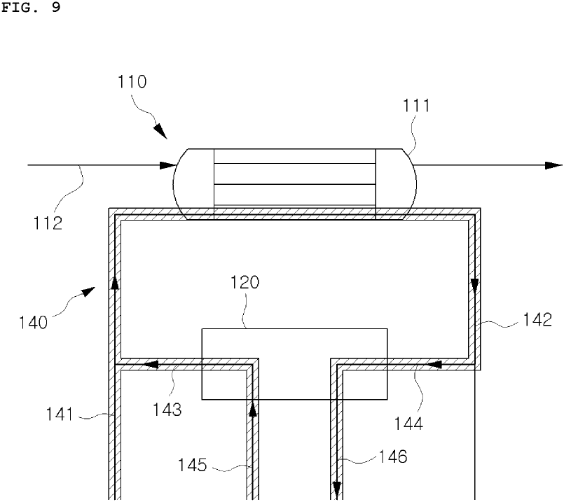

Referring to FIG. 9, in a seventh mode of the present disclosure, the seawater is supplied to the heat exchanger 110 through the first supply line 141 and the seawater, which is supplied to the reservoir 120 through the second supply line 145, is supplied to the heat exchanger 110 through the supply connection line 143 and the first supply line 141. The seawater passing through the heat exchanger 110 is discharged to the sea through the first discharge line 142, the discharge connection line 144, the reservoir 120, and the second discharge line 146. In the seventh mode, some of the seawater flowing into the device is directly supplied to the heat exchanger 110, and the other portion thereof is supplied to the reservoir 120 through the second supply line 145 to be preheated, and then is supplied to the heat exchanger 110 to optimally maintain the amount of heat required for vaporization of the liquefied natural gas. In the seventh mode, the seawater discharged from the heat exchanger 110 is heated in the reservoir 120 and then discharged to the sea through the second discharge line 146.

As described above, according to the heat exchange device 100 using seawater according to the present disclosure, it is possible to vaporize the liquefied natural gas into the natural gas using the seawater, to cool the data center using the seawater in a state of being cooled by heat-exchanging with the liquefied natural gas, and to prevent damage to the marine ecosystem by discharging the seawater reheated by the data center to the sea.

1. A heat exchange device using seawater comprising:
a heat exchanger through which liquefied natural gas is passed and vaporized;
a first supply line connected to the heat exchanger and supplying seawater to the heat exchanger;
a first discharge line through which the seawater discharged from the heat exchanger flows in;
a reservoir to which the seawater flows in and out;
a heat source installed in the reservoir and heating the seawater flowed in the reservoir;
a discharge connection line connecting the first discharge line and the reservoir, and selectively supplying the seawater flowing through the first discharge line to the reservoir; and
a second discharge line for discharging the seawater from the reservoir to the sea.

2. The heat exchange device using seawater according to claim 1, further comprising:
a case surrounding the heat source.

3. The heat exchange device using seawater of claim 2,
wherein a lower portion of the heat source is immersed the reservoir, and
wherein the case includes a bottom case surrounding the lower portion of the heat source.

4. The heat exchange device using seawater of claim 3,
wherein the heat source is accommodated inside the reservoir, and
wherein the case further includes an upper cover that is disposed on the upper side of the bottom case and surrounds an upper portion of the heat source.

5. The heat exchange device using seawater of claim 1,
wherein the heat exchanger includes
a heat exchange cylinder having a hollow cylindrical shape; and
a gas flow line which penetrates the inside of the heat exchange cylinder and through which liquefied natural gas passes.

6. The heat exchange device using seawater of claim 1,
wherein the heat source uses the seawater which can exchange heat in a data center.

7. The heat exchange device using seawater of claim 1, further comprising:
a supply connection line connecting the first supply line and the reservoir, and selectively supplying the seawater flowed in the reservoir to the first supply line; and
a second supply line through which the seawater is flowed in the reservoir from the sea.

8. The heat exchange device using seawater of claim 1,
Wherein, in a first mode, the seawater supplied to the heat exchanger from the sea through the first supply line is discharged to the sea through the first discharge line.

9. The heat exchange device using seawater of claim 1,
Wherein, in a second mode, the seawater supplied to the heat exchanger from the sea through the first supply line is supplied to the reservoir through the first discharge line and the discharge connection line, and then is discharged to the sea through the second discharge line.

10. The heat exchange device using seawater of claim 7,
Wherein, in a third mode, the seawater circulates through a closed loop that sequentially connects the reservoir, the supply connection line, the first supply line, the heat exchanger, the first discharge line, the discharge connection line, and the reservoir.

11. The heat exchange device using seawater of claim 7,
Wherein, in a fourth mode, the seawater supplied to the reservoir through the second supply line flows along the supply connection line, the first supply line, the heat exchanger, the first discharge line, the discharge connection line, the reservoir, and the second discharge line.

12. The heat exchange device using seawater of claim 7,
Wherein, in a fifth mode, the seawater supplied to the heat exchanger through the first supply line is supplied to the reservoir through the first discharge line and the discharge connection line, some of the seawater supplied to the reservoir is supplied to the first supply line through the supply connection line, and the other thereof is discharged to the sea through the second discharge line.

13. The heat exchange device using seawater of claim 7,
Wherein, in a sixth mode, the seawater supplied to the heat exchanger through the first supply line circulates through the first discharge line, the discharge connection line, the reservoir, the supply connection line, and the first supply line.

14. The heat exchange device using seawater of claim 7,
Wherein, in a seventh mode, the seawater is supplied to the heat exchanger through the first supply line, and the seawater supplied to the reservoir through the second supply line is supplied to the heat exchanger through the supply connection line and the first supply line, and the seawater passing through the heat exchanger is discharged to the sea through the first discharge line, the discharge connection line, the reservoir, and the second discharge line.
